(19) United States
(12) Patent Application Publication
(10) Pub. No.: US 2021/0020358 A1
(43) Pub. Date: Jan. 21, 2021

(54) ELECTRICAL ASSEMBLIES INCLUDING COUPLERS FOR CANCELING MAGNETIC FLUX

(71) Applicant: Maxim Integrated Products, Inc., San Jose, CA (US)

(72) Inventors: Jaeyoung Choi, Portland, OR (US); Jonathan C.H. (Cheng-Hsien) Hung, Allen, TX (US); Tao Huang, San Francisco, CA (US)

(21) Appl. No.: 16/929,567

(22) Filed: Jul. 15, 2020

Related U.S. Application Data
(60) Provisional application No. 62/874,496, filed on Jul. 15, 2019.

(51) Int. Cl. H01F 27/34; H01F 27/38; H01F 27/36

(52) U.S. Cl. CPC H01F 27/346; H01F 27/363; H01F 27/38

(57) ABSTRACT

An electrical assembly includes (a) a first inductor including a first winding wound around a first winding axis, (b) a second inductor separated from the first inductor in a first direction, and (c) a coupler at least partially disposed between the first inductor and the second inductor in the first direction, the coupler forming at least part of an electrical circuit enabling electric current to flow through the coupler, and the coupler being asymmetric with respect to a dividing axis of the first inductor extending in a second direction that is orthogonal to the first direction.

### RELATED APPLICATIONS

This application claims benefit of priority to U.S. Provisional Patent Application Ser. No. 62/874,496, filed on Jul. 15, 2019, which is incorporated herein by reference.

### BACKGROUND

Inductors are used extensively in electronic devices. For example, inductors are commonly used for energy storage in power conversion circuits of electronic devices. Additionally, inductors are frequently used for filtering electrical signals in electronic devices. Furthermore, inductors are often used in resonant circuits, such as resonant tank circuits, of electronic devices.

Miniaturization of electronic devices has necessitated that two or more inductors frequently be in close physical proximity, such as on a common printed circuit board (PCB) or in a common integrated circuit. Consequently, there may unwanted interaction between two or more inductors where magnetic flux from one inductor undesirably couples to one or more other inductors. Such undesirable magnetic coupling of inductors degrades inductor operation.

Unwanted magnetic coupling between inductors can be reduced, or even eliminated, by increasing distance between the inductors. However, increasing distance between inductors is often not feasible in modern electronic devices due to space constraints. Unwanted magnetic coupling between inductors can also be reduced by decreasing size of an “aggressor” inductor, i.e. an inductor that generates magnetic flux that interferes with operation of another inductor. It is frequently impractical, though, to sufficiently decrease size of an aggressor inductor to prevent unwanted magnetic coupling, due to constraints such as minimum quality (Q)-factor requirements and maximum impedance specifications.

### BRIEF DESCRIPTION OF THE DRAWINGS

FIG. 1 is a top plan view of an electrical assembly including a coupler for canceling magnetic flux, according to an embodiment.

FIG. 2 is a side elevational view of the FIG. 1 electrical assembly.

FIG. 3 is a top plan view of one embodiment of the FIG. 1 electrical assembly where opposing ends of the coupler are electrically connected within a substrate.

FIG. 4 is a cross-sectional view of the FIG. 3 electrical assembly taken along line 4A-4A of FIG. 3.

FIG. 5 is a top plan view of one embodiment of the FIG. 1 electrical assembly where opposing ends of the coupler are electrically connected by conductive elements within a substrate and by a conductive element external to the substrate.

FIG. 6 is a cross-sectional view of the FIG. 5 electrical assembly taken along line 6A-6A of FIG. 5.

FIG. 7 is a schematic diagram illustrating an operating principle of a coupler disposed between two inductors, according to an embodiment.

FIG. 8 is a schematic diagram illustrating operation of a coupler disposed to the right of a pair of inductors.

FIG. 9 is a side elevational view of an integrated circuit, according to an embodiment.

FIG. 10 is a cross-sectional view of the FIG. 9 integrated circuit taken along line 10A-10A of FIG. 9.

FIG. 11 is a top plan view of an electrical assembly including spiral inductors and a coupler for canceling magnetic flux, according to an embodiment.

FIG. 12 is a side elevational view of the FIG. 11 electrical assembly.

FIG. 13 is a top plan view of an electrical assembly including differential inductors and a coupler for canceling magnetic flux, according to an embodiment.

FIG. 14 is a side elevational view of the FIG. 13 electrical assembly.

FIG. 15 is a top plan view of an electrical assembly including a coupler with two portions, according to an embodiment.

FIG. 16 is a side elevational view of the FIG. 15 electrical assembly.

FIG. 17 is a top plan view of an electrical assembly including three inductors and a coupler for canceling magnetic flux, according to an embodiment.

FIG. 18 is a top plan view of an electrical assembly including an asymmetric coupler which surrounds an inductor, according to an embodiment.

FIG. 19 is a top plan view of an electrical assembly including an asymmetric coupler which partially surrounds an inductor, according to an embodiment.

FIG. 20 is a top plan view of another electrical assembly including an asymmetric coupler which partially surrounds an inductor, according to an embodiment.

FIG. 21 is a top plan view of an electrical assembly including couplers which can be selectively enabled and disabled, according to an embodiment.

FIG. 22 is a top plan view of an electrical assembly used in simulations of coupler operation.

FIG. 23 is a top plan view of another electrical assembly used in simulations of coupler operation.

FIG. 24 is a flow chart illustrating a method for canceling magnetic flux in an electrical assembly, according to an embodiment.

### DETAILED DESCRIPTION OF THE EMBODIMENTS

Disclosed herein are electrical assemblies including couplers for canceling magnetic flux. The couplers advantageously help minimize undesired magnetic coupling between inductors without requiring increased distance between inductors or decreased inductor size.

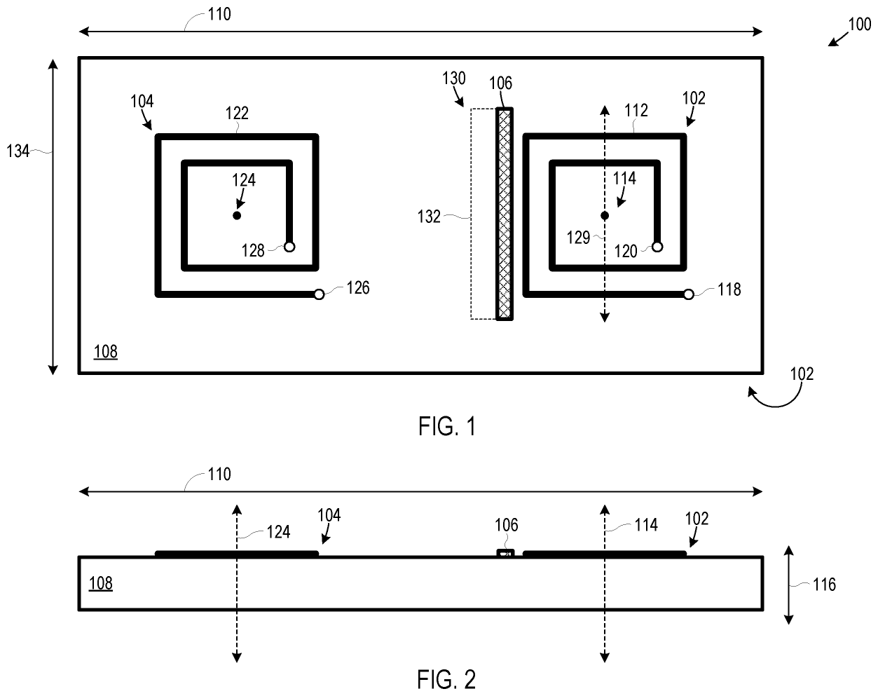

FIG. 1 is a top plan view of an electrical assembly 100, and FIG. 2 is an elevational view of a side 102 of electrical assembly 100. Electrical assembly 100 is one embodiment of the new electrical assemblies including couplers. Electrical assembly 100 includes a first inductor 102, a second inductor 104, a coupler 106, and a substrate 108. Substrate 108 is, for example, a printed circuit board (PCB) or a portion of an integrated circuit. Inductors 102 and 104 are formed on substrate 108, and coupler 106 is configured to at least partially cancel magnetic flux generated by first inductor 102 at second inductor 104. Thus, coupler 106 helps minimize undesired magnetic coupling of first inductor 102 and second inductor 104, i.e. unwanted interference in operation of second inductor 104 from magnetic flux generated by first inductor 102. First inductor 102 and second inductor 104 are separated from each other in a direction 110, and coupler 106 is at least partially disposed between first inductor 102 and second inductor 104 in direction 110.

First inductor 102 includes a first winding 112 wound around a first winding axis 114 and extending in a direction 116. Although direction 116 is orthogonal to direction 110 in this embodiment, direction 116 could be offset from direction 110 at a different angle, i.e. other than 90 degrees, as long as direction 116 is different from direction 110. First winding 112 is formed, for example, by a PCB conductive “trace” or by a metal layer within an integrated circuit. The number of turns formed by first winding 112 may be varied as a design choice. Opposing ends of first winding 110 are optionally connected to respective terminals 118 and 120, which provide electrical access to first inductor 102.

Second inductor 104 includes a second winding 122 wound around a second winding axis 124 extending in direction 116. Second winding 122 is formed, for example, by a PCB conductive trace or by a metal layer within an integrated circuit. The number of turns formed by second winding 122 may be varied as a design choice. Opposing ends of second winding 112 are optionally connected to respective terminals 126 and 128, which provide electrical access to second inductor 104. Although first inductor 102 and second inductor 104 have the same configuration in electrical assembly 100, the two inductors may have different configurations without departing from the scope hereof. Some example, in some alternate embodiments, first inductor 102 and second inductor 104 have different shapes and/or form different number of winding turns. As another example, in some alternate embodiments, first winding axis 114 and second winding axis 124 do not extend in the same direction, i.e. the two winding axes are angularly offset from each other.

Coupler 106 is formed on substrate 108. Coupler 106 is, for example, a PCB conductive trace or a metal layer within an integrated circuit. Importantly, coupler 106 is asymmetric with respect to inductor 102. For example, in some embodiments, coupler 106 is asymmetric with respect to a dividing axis 129 of first inductor 102, where dividing axis 129 extends in a direction 134 that is at least substantially orthogonal to direction 110. In this document, the term “substantially” means within plus or minus ten percent. Accordingly, a first direction is substantially orthogonal to a second direction if the first direction is angularly offset from the second direction by an angle ranging from 81 degrees to 99 degrees. Dividing axis 129 divides first inductor 102 into left and right portions, and in some embodiments, dividing axis 129 intersects winding axis 114. Applicant has found that coupler 106 being asymmetric with respect to dividing axis 129 helps achieve high performance by generating magnetic flux which helps cancel magnetic flux at second inductor 104 that originates from first inductor 102, as discussed below. It should be noted, however, that first inductor 102 need not necessarily be symmetric with respect to dividing axis 129. In the example of FIGS. 1 and 2, coupler 106 does not completely surround first inductor 102, as seen when electrical assembly 100 is viewed cross-sectionally along the direction of first winding axis 114, which results in coupler 106 being asymmetric with respect to dividing axis 129.

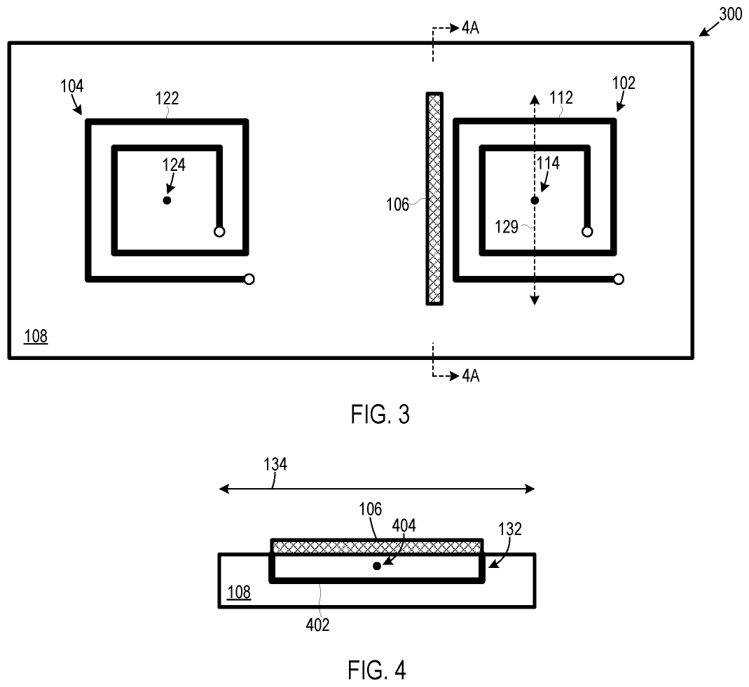

Coupler 106 forms at least part of an electrical circuit 130 enabling electric current to flow through the coupler. Dashed line 132 in FIG. 1 represents additional electrical conductors, e.g. PCB traces, integrated circuit metal layers, and/or external conductors, which cooperate with coupler 106 to form electrical circuit 130. The physical configuration of additional electrical conductors 132 may vary as long as they enable coupler 106 to generate a net magnetic flux at second inductor 104 which opposes magnetic flux from first inductor 102. Discussed below with respect to FIGS. 3-6 are two examples of possible configurations of additional electrical conductors 132. It should be realized, though, that additional electrical conductors 132 can take other forms without departing from the scope hereof.

FIG. 3 is a top plan view of an electrical assembly 300, and FIG. 4 is a cross-sectional view of electrical assembly 300 taken along line 4A-4A of FIG. 3. Electrical assembly 300 is an embodiment of electrical assembly 100 where additional electrical conductors 132 are implemented by a conductive element 402 in substrate 108. Conductive element 402 is, for example, a metal layer within a PCB or metal layer within an integrated circuit. Conductive element 402 connects opposing ends of coupler 106 in direction 134, such that coupler 106 and conductive element 402 collectively form electrical circuit 130. Electrical circuit 130 forms at least one turn around an axis 404 extending in direction 110, i.e. in a direction different from that of first winding axis 114.

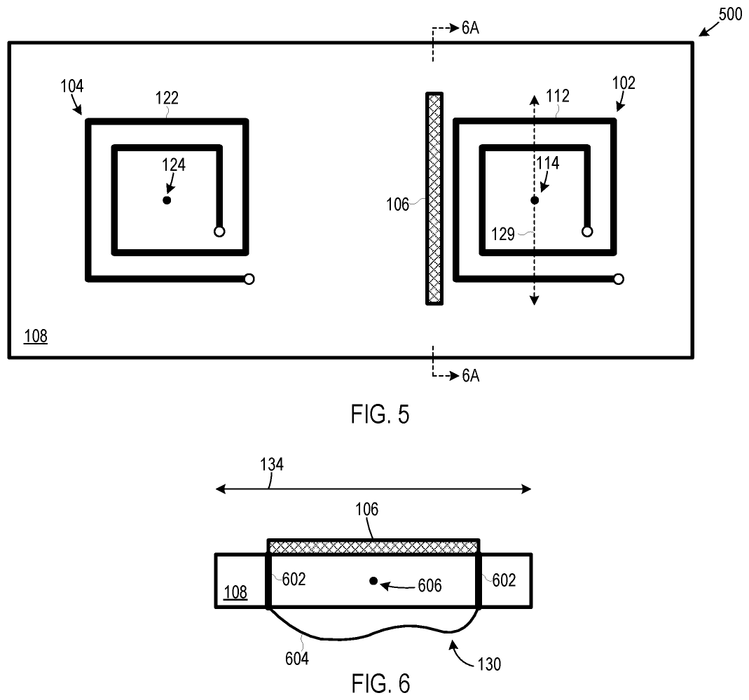

FIG. 5 is a top plan view of an electrical assembly 500, and FIG. 6 is a cross-sectional view of electrical assembly 500 taken along line 6A-6A of FIG. 5. Electrical assembly 500 is an embodiment of electrical assembly 100 where additional electrical conductors 132 are implemented by conductive elements 602 in substrate 108 and by a conductive element 604 external to substrate 108. Conductive elements 602 are, for example, vias within a PCB or an integrated circuit. Conductive element 604 is, for example, a wire or a PCB conductive trace of an additional PCB (not shown) adjacent to substrate 108. Conductive elements 602 and 604 connect opposing ends of coupler 106 in direction 134, such that coupler 106 and conductive elements 602 and 604 collectively form electrical circuit 130. Electrical circuit 130 forms a turn around an axis 606 extending in direction 110, i.e. in a direction different from that of first winding axis 114.

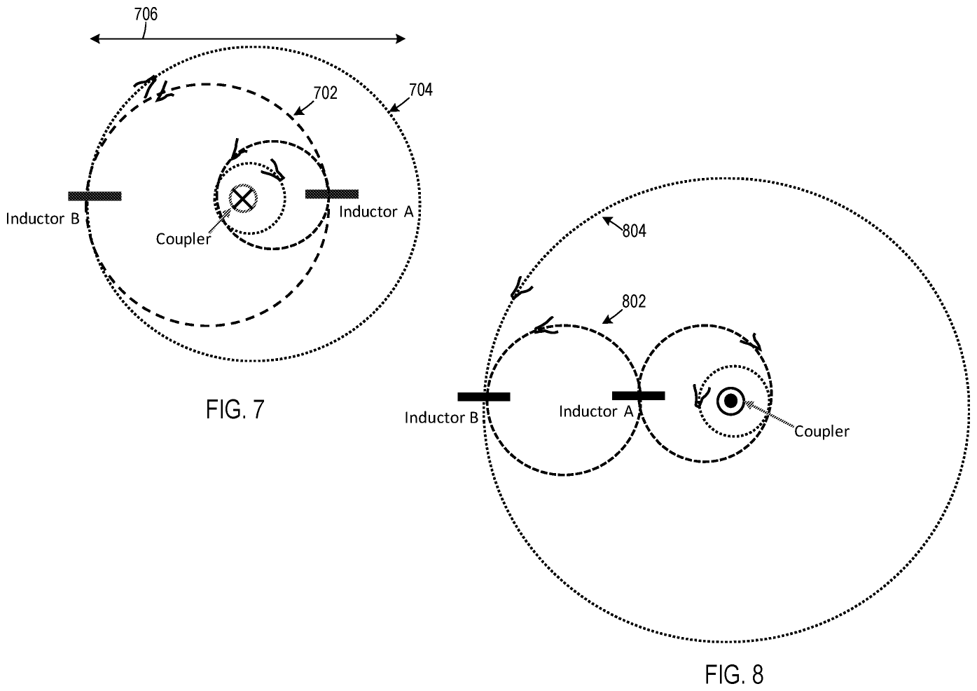

FIG. 7 is a schematic diagram illustrating an operating principle of a coupler. Inductors A and B of FIG. 7 are, for example, first and second inductors 102 and 104, respectively, and the coupler of FIG. 7 is, for example, coupler 106. The coupler is disposed between inductors A and B in a direction 706. In this example, electric current flowing through inductor A generates a magnetic flux 702 flowing in a counter-clockwise direction, as seen when looking into the page of FIG. 7. The coupler is configured so that part of magnetic flux 702 induces an electric current flowing through the coupler and flowing into the page of FIG. 7, which is represented by a letter “X” within the coupler. The electric current flowing through the coupler induces a magnetic flux 704 flowing in a clockwise direction, as seen when looking into the page of FIG. 7. As evident from FIG. 7, magnetic flux 704 from the coupler at least partially cancels, i.e. destructively interferes with, magnetic flux 702 from inductor A at inductor B. Thus, the coupler helps minimize interaction between inductors A and B.

The coupler is disposed between inductors A and B in FIG. 7, as mentioned above. Now consider FIG. 8, where the coupler is moved to the right of inductor A, instead of being disposed between inductors A and B. Similar to the example of FIG. 7, inductor A generates magnetic flux 802 flowing in a counter-clockwise direction. However, the relative location of the coupler causes it to generate magnetic flux 804 which also flows in a counter-clockwise direction. Consequently, magnetic flux 802 from inductor A and magnetic flux from the coupler add, instead of cancel, at inductor B. Therefore, the configuration of the coupler in FIG. 8 increases, instead of decreases, interaction between inductors A and B.

Thus, FIGS. 7 and 8 illustrate the importance of coupler 106 being between first inductor 102 and second inductor 104 in electrical assembly 100. If coupler 106 were instead disposed to the right of first inductor 102, coupler 106 would increase interaction between first inductor 102 and second inductor 104. Additionally, modifying coupler 106 so that it is symmetric with respect to a dividing axis of inductor A, e.g. such that coupler 106 forms a symmetrical loop around inductor A, would degrade coupler 106 operation by causing part of magnetic flux generated by the coupler to constructively interfere with magnetic flux from inductor A. Accordingly, it is important that the coupler be completely disposed between inductors A and B, or that portions of the coupler to the right of inductor A have minimal influence on inductor B.

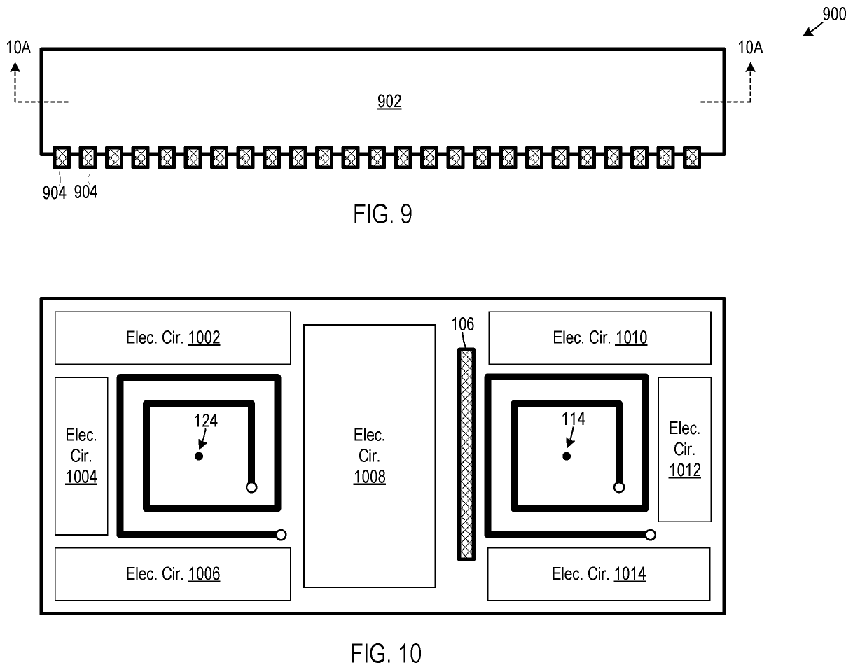

As mentioned above, some embodiments of electrical assembly 100 of FIG. 1 are part of an integrated circuit. FIGS. 9 and 10 illustrate one example of an integrated circuit embodiment. Specifically, FIG. 9 is a side elevational view of an integrated circuit 900, and FIG. 10 is a cross-sectional view of integrated circuit 900 taken along line 10A-10A of FIG. 9. Integrated circuit 900 includes a body 902, electrical contacts 904, electronic circuitry 1002-1014, and an embodiment of electrical assembly 100. Body 902 encapsulates integrated circuit 900, and body 902 is formed, for example, of a plastic material or of a ceramic material. Electrical contacts 904 provide electrical access to integrated circuit 900, and only two instances of electrical contacts 904 are labeled in FIG. 9. Electrical contacts 904 include, for example, surface-mount electrical contracts and/or through-hole electrical contacts.

Electronic circuitry 1002-1014 is disposed within integrated circuit 900 around the elements of electrical assembly 100, e.g. around first inductor 102 and second inductor 104. Details of electronic circuitry 1002-1004 are not shown to promote illustrative clarity. The number, size, shape, and configuration of electronic circuits in integrated circuit 900 may vary without departing from the scope hereof.

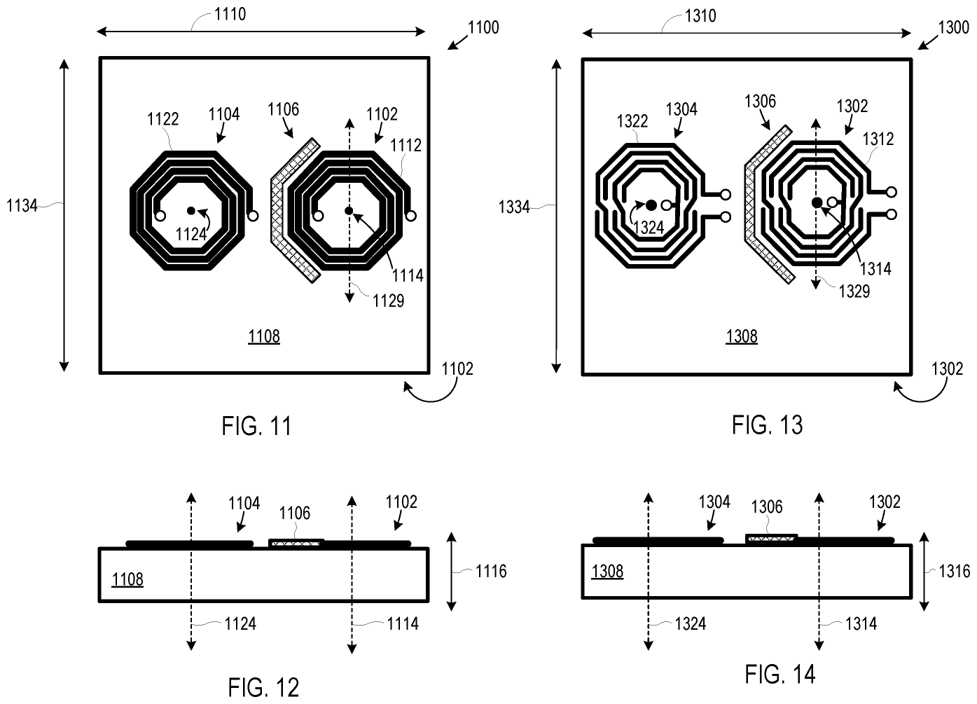

FIG. 11 is a top plan view of an electrical assembly 1100, which is an alternate embodiment of electrical assembly 100 including spiral inductors. Electrical assembly 1100 includes a first inductor 1102, a second inductor 1104, a coupler 1106, and a substrate 1108. Substrate 1108 is, for example, a PCB or a portion of an integrated circuit. Inductors 1102 and 1104 are formed on substrate 1108, and coupler 1106 is configured to at least partially cancel magnetic flux generated by first inductor 1102 at second inductor 1104, in a manner similar to that discussed above with respect to coupler 106.

First inductor 1102 includes a first winding 1112 wound in a spiral shape around a first winding axis 1114, where first winding axis 1114 extends in a direction 1116. Although direction 1116 is orthogonal to direction 1110 in this embodiment, direction 1116 could be offset from direction 1110 at a different angle, i.e. other than 90 degrees, as long as direction 1116 is different from direction 1110. First winding 1112 is formed, for example, by a PCB conductive trace or by a metal layer within an integrated circuit. The number of turns formed by first winding 1112 may be varied as a design choice. Opposing ends of first winding 1112 are optionally connected to respective terminals (not labeled for illustrative clarity), which provide electrical access to first inductor 1102.

Second inductor 1104 includes a second winding 1122 wound around a second winding axis 1124 extending in direction 1116. Second winding 1122 is formed, for example, by a PCB conductive trace or by a metal layer within an integrated circuit. The number of turns formed by second winding 1122 may be varied as a design choice. Opposing ends of second winding 1112 are optionally connected to respective terminals (not labeled for illustrative clarity), which provide electrical access to second inductor 1104.

Coupler 1106 is formed on substrate 1108 between first inductor 1102 and second inductor 1122 in direction 1110. Coupler 1106 is, for example, a PCB conductive trace or a metal layer within an integrated circuit. Coupler 1106 forms part of an electrical circuit enabling electric current to flow through the coupler. Additional electrical conductors (not shown), such as additional electrical conductors similar to those of FIG. 4 or 6, cooperate with coupler 1106 to form the electrical circuit. Importantly, coupler 1106 is asymmetric with respect to first inductor 1102. For example, in some embodiments, coupler 1106 is asymmetric with respect to a dividing axis 1129 of first inductor 1102, where dividing axis 1129 extends in a direction 1134 that is at least substantially orthogonal to direction 1110. Dividing axis 1129 intersects first winding axis 1114. Coupler 1106 generates magnetic flux which at least partially cancels magnetic flux from first inductor 1102 at second inductor 1104.

FIG. 13 is a top plan view of an electrical assembly 1300, which is an alternate embodiment of electrical assembly 100 including differential inductors. Electrical assembly 1300 includes a first inductor 1302, a second inductor 1304, a coupler 1306, and a substrate 1308. Substrate 1308 is, for example, a PCB or a portion of an integrated circuit. Inductors 1302 and 1304 are formed on substrate 1308, and coupler 1306 is configured to at least partially cancel magnetic flux generated by first inductor 1302 at second inductor 1304, in a manner similar to that discussed above with respect to coupler 106.

First inductor 1302 includes a first winding 1312 wound around a first winding axis 1314, where first winding axis 1314 extends in a direction 1316. Although direction 1316 is orthogonal to direction 1310 in this embodiment, direction 1316 could be offset from direction 1310 at a different angle, i.e. other than 90 degrees, as long as direction 1316 is different from direction 1310. First winding 1312 is formed, for example, by a PCB conductive trace or by a metal layer within an integrated circuit. The number of turns formed by first winding 1312 may be varied as a design choice. Opposing ends of first winding 1312 and a center of first winding 1312 are optionally connected to respective terminals (not labeled for illustrative clarity), which provide electrical access to first inductor 1302.

Second inductor 1304 includes a second winding 1322 wound around a second winding axis 1324 extending in direction 1316. Second winding 1322 is formed, for example, by a PCB conductive trace or by a metal layer within an integrated circuit. The number of turns formed by second winding 1322 may be varied as a design choice. Opposing ends of second winding 1322 and a center of second winding 1322 are optionally connected to respective terminals (not labeled for illustrative clarity), which provide electrical access to second inductor 1304.

Coupler 1306 is formed on substrate 1308 between first inductor 1302 and second inductor 1304 in direction 1310. Coupler 1306 is, for example, a PCB conductive trace or a metal layer within an integrated circuit. Coupler 1306 forms part of an electrical circuit enabling electric current to flow through the coupler. Additional electrical conductors (not shown), such as additional electrical conductors similar to those of FIG. 4 or 6, cooperate with coupler 1306 to form the electrical circuit. Importantly, coupler 1306 is asymmetric with respect to first inductor 1302. For example, in some embodiments, coupler 1306 is asymmetric with respect to a dividing axis 1329 of first inductor 1302, where dividing axis 1329 extends in a direction 1334 that is at least substantially orthogonal to direction 1310. Dividing axis 1329 intersects first winding axis 1314. Coupler 1306 generates magnetic flux which at least partially cancels magnetic flux from first inductor 1302 at second inductor 1304.

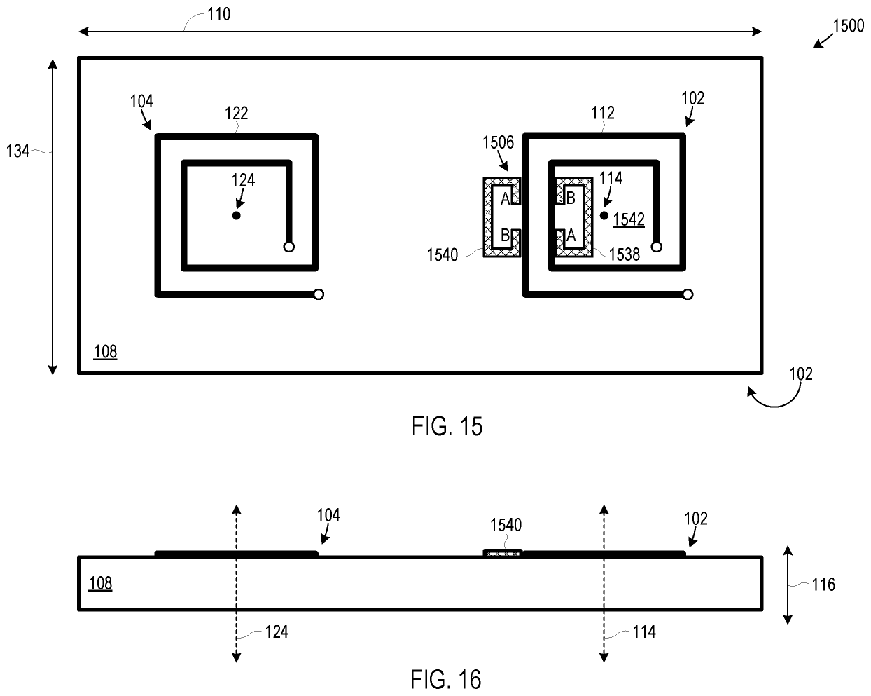

Referring again to FIG. 1, first inductor 102, second inductor 104, and coupler 106 are non-overlapping with each other, as seen when electrical assembly 100 is viewed cross-sectionally along direction 116 (into the page of FIG. 1). However, coupler 106 could be modified to at least partially overlap first inductor 102 if (a) a portion of the coupler is disposed between first inductor 102 and second inductor 104 in direction 110 and (b) the coupler is configured to generate a magnetic flux which at least partially cancels the magnetic flux from first inductor 102 at second inductor 104. For example, FIG. 15 is a top plan view of an electrical assembly 1500, which is an alternate embodiment of electrical assembly 100 where coupler 106 is replaced with coupler 1506. FIG. 16 is an elevational view of side 102 of electrical assembly 1500.

Coupler 1506 includes a first portion 1538 and a second portion 1540. First portion 1538 is disposed within a first area 1542, where first area 1542 is an area enclosed by first winding 112, as seen when electrical assembly 1500 is viewed cross-sectionally along direction 116 (into the page of FIG. 15). Second portion 1540 is disposed outside of first area 1542, as seen when electrical assembly 1500 is viewed cross-sectionally along direction 116. Second portion 1540 is also disposed between first inductor 102 and second inductor 104 in direction 110. First portion 1538 and second portion 1540 are cross-connected. Specifically, end A of first portion 1538 is electrically coupled to end A of second portion 1540, and end B of first portion 1538 is electrically coupled to end B of second portion 1540. Electrical connections between first portion 1538 and second portion 1540 are not shown in FIG. 15 for illustrative clarity. Coupler 1506 is asymmetric with respect to first inductor 102. For example, coupler 1506 is asymmetric with respect to dividing axis 129 (not shown in FIG. 15 for illustrative clarity). The positioning of first portion 1538 and second portion 1540 relative to first winding 112, as well as the cross connections between these portions, enables coupler 1506 to help cancel magnetic flux from first inductor 102 at second inductor 104.

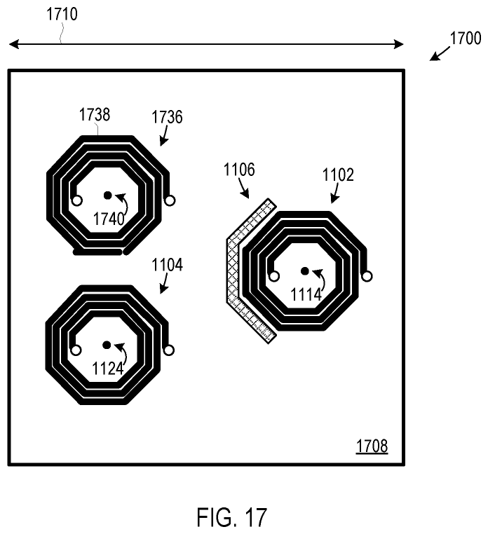

Certain embodiments of the couplers disclosed herein could be configured to minimize undesired magnetic coupling between a first inductor and two or more additional inductors. For example, FIG. 17 is a top plan view of an electrical assembly 1700 including an instance of first inductor 1102 (FIG. 11), an instance of second inductor 1104, an instance of coupler 1106, and a third inductor 1736, formed on a substrate 1708. Substrate 1708 is, for example, a PCB or a portion of an integrated circuit. Third inductor 1736 is similar to second inductor 1104, i.e. third inductor 1736 includes a third winding 1738 wound in a spiral shape around a third winding axis 1740. Coupler 1106 is disposed between first inductor 1102 and each of second inductor 1104 and third inductor 1736 in a direction 1710. Accordingly, coupler 1106 helps prevent magnetic flux from first inductor 1102 from coupling to either second inductor 1104 or third inductor 1736, in a manner consistent with that illustrated in FIG. 7.

The couplers illustrated in FIGS. 1-6 and 10-17 do not completely surround their respective first inductors, as seen when their respective electrical assemblies are viewed cross-sectionally along the direction of the first winding axis. However, the couplers could be modified so that they surround their respective first inductors, or substantially surround their respective first inductors, as long as (1) each coupler is asymmetric with respect to its respective first inductor, e.g. it asymmetric with respect to a dividing axis of its respective first inductor, and (2) each coupler is weighted toward its respective second inductor. A coupler is weighted toward its respective second inductor by being configured so that a majority of magnetic flux from the coupler at the second inductor cancels magnetic flux from the first inductor.

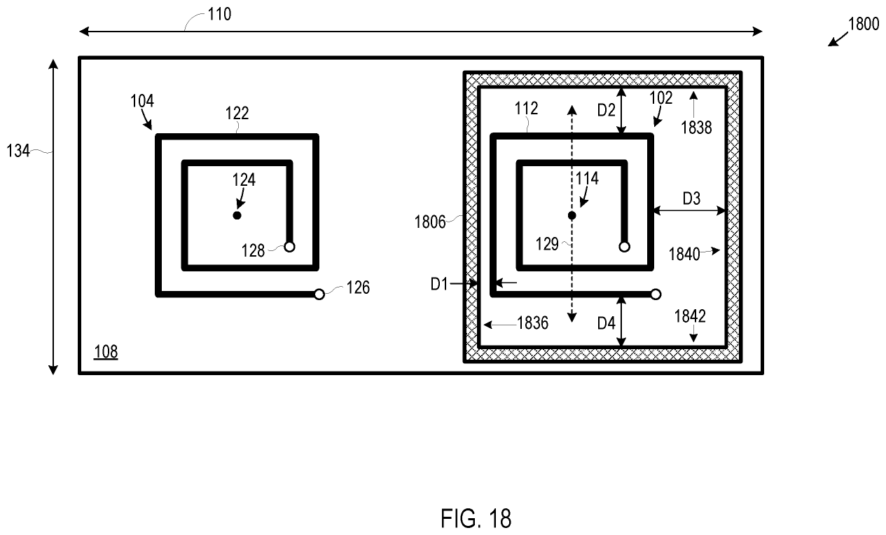

For example, FIG. 18 is a top plan view of an electrical assembly 1800, which is an alternate embodiment of electrical assembly 1800 where coupler 106 is replaced with coupler 1806. Coupler 1806 surrounds first inductor 102; however, coupler 1806 is asymmetric with respect to dividing axis 129. In particular, coupler 1806 includes sides 1836, 1838, 1840, and 1842. Side 1836, which is between first inductor 102 and second inductor 104 in direction 110, is separated from first inductor 102 by a separation distance D1. Sides 1838, 1840, and 1842 of coupler 1806 are separated from first inductor 102 by separation distances D2, D3, and D4, respectively. Importantly, D1 is less than each of D2, D3, and D4. Consequently, coupler 1806 is asymmetric with respect to dividing axis 129, and side 1836 is more-strongly magnetically coupled to first inductor 102 than sides 1838, 1840, and 1842. Therefore, coupler 1806 is weighted toward second inductor 104. Accordingly, magnetic flux generated by coupler 1806 helps cancel magnetic flux from first inductor 102. In some embodiments, D1 is no more than fifty percent of each of D2, D3, and D4. Ideally, D1 is much smaller than each of D2, D3, and D4, to maximize performance of coupler 1806.

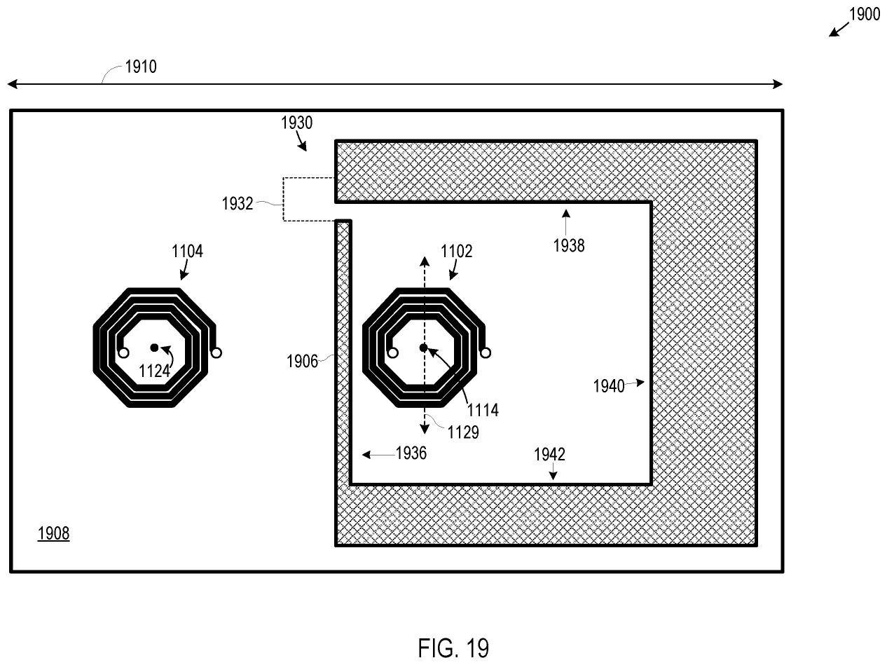

As another example, FIG. 19 is a top plan view of an electrical assembly 1900 including an instance of first inductor 1102 (FIG. 11), an instance of second inductor 1104, a coupler 1906, and a substrate 1908. First inductor 1102, second inductor 1104, and coupler 1906 are each formed on substrate 1908. Substrate 1908 is, for example, a PCB or a portion of an integrated circuit. Coupler 1906 forms nearly a complete loop around first inductor 1102, and coupler 1906 forms at least part of an electrical circuit 1930 enabling electric current to flow through the coupler. Dashed line 1932 in FIG. 19 represents additional electrical conductors, e.g. PCB traces, integrated circuit metal layers, and/or external conductors, which cooperate with coupler 1906 to form electrical circuit 1930. The physical configuration of additional electrical conductors 1932 may vary.

Coupler 1906 includes four sides 1936, 1938, 1940, and 1942, where side 1936 is disposed between first inductor 1102 and second inductor 1104 in a direction 1910. Importantly, side 1936 is closer to first inductor 1102 than remaining sides 1938, 1940, and 1942, so that coupler 1906 is asymmetric with respect to dividing axis 1129, and side 1936 is more-strongly magnetically coupled to first inductor 102 than sides 1938, 1940, and 1942. Therefore, coupler 1906 is weighted toward second inductor 1104. Accordingly, magnetic flux generated by coupler 1906 helps cancel magnetic flux from first inductor 1102 at second inductor 1104.

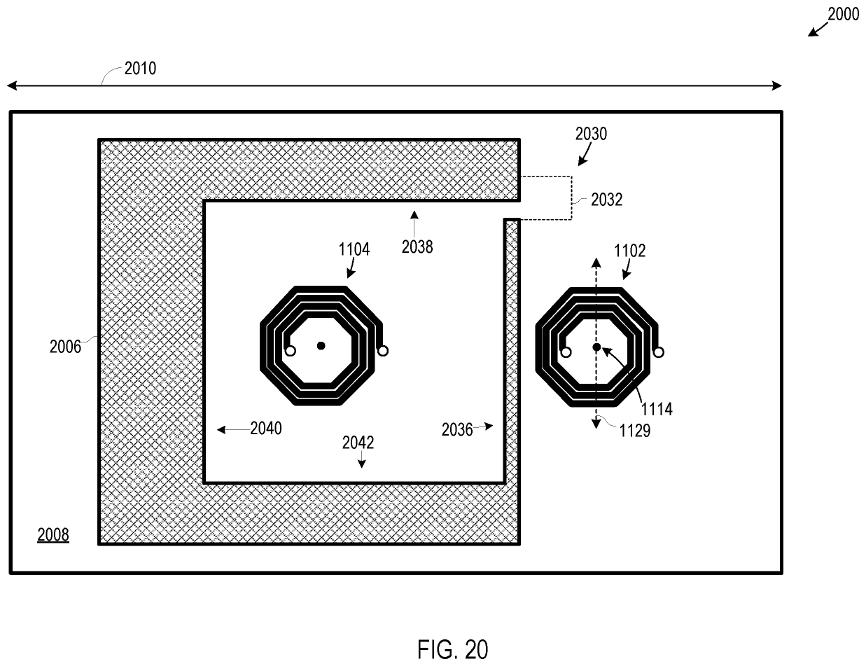

FIG. 20 is a top plan view of an electrical assembly 2000 including an instance of first inductor 1102, an instance of second inductor 1104, a coupler 2006, and a substrate 2008. First inductor 1102, second inductor 1104, and coupler 2006 are each formed on substrate 2008. Substrate 2008 is, for example, a PCB or a portion of an integrated circuit. In contrast to coupler 1906 of electrical assembly 1900, coupler 2006 forms nearly a complete loop around second inductor 1104. Additionally, coupler 2006 forms at least part of an electrical circuit 2032 enabling electric current to flow through the coupler. Dashed line 2032 in FIG. 20 represents additional electrical conductors, e.g. PCB traces, integrated circuit metal layers, and/or external conductors, which cooperate with coupler 2006 to form electrical circuit 2030. The physical configuration of additional electrical conductors 2032 may vary.

Coupler 2006 includes four sides 2036, 2038, 2040, and 2042, where side 2036 is disposed between first inductor 1102 and second inductor 1104 in a direction 2010. Importantly, side 2036 is closer to first inductor 1102 than remaining sides 2038, 2040, and 2042, so that coupler 2006 is asymmetric with respect to dividing axis 1129, and side 2036 is more-strongly magnetically coupled to first inductor 1102 than sides 2038, 2040, and 2042. Therefore, coupler 2006 is weighted toward second inductor 1104. Accordingly, magnetic flux generated by coupler 2006 helps cancel magnetic flux from first inductor 1102.

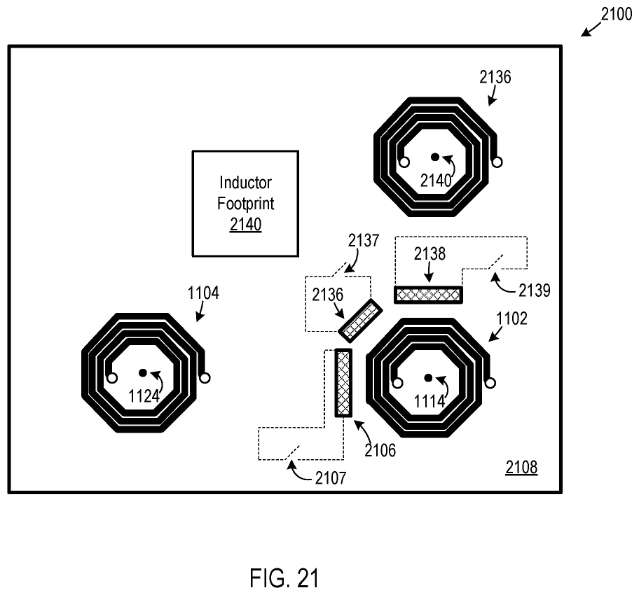

The couplers disclosed herein could be configured so that they are selectively enabled and disabled. For example, FIG. 21 is a top plan view of an electrical assembly 2100 including an instance of first inductor 1102, an instance of second inductor 1104, and an instance of third inductor 2136 (FIGS. 11 and 21), formed on a substrate 2108. Substrate 2108 is, for example, a PCB or a portion of an integrated circuit. Coupler 1106 is replaced with three couplers 2106, 2136, and 2138 in electrical assembly 2100. Each of couplers 2106, 2136, and 2138 is electrically coupled to a respective switching device 2107, 2137, and 2139, symbolically shown by dashed lines in FIG. 21. Switching device 2107 enables coupler 2106 to be enabled and disabled depending on an operating state of switching device 2107. In particular, coupler 2106 is enabled by controlling switching device 2107 to operate in its closed state, such that electric current can flow through coupler 2106. Conversely, coupler 2106 is disabled by controlling switching device 2107 to operate in its open state, such that electric current cannot flow through coupler 2106. Couplers 2136 and 2138 can be selectively enabled and disabled in a similar manner by controlling operating states of their respective switching devices 2137 and 2139.

The ability to selectively enable and disable couplers 2106, 2136, and 2138 may be valuable, for example, when the configuration of electrical assembly 2100 may vary. For example, in some embodiments, electrical assembly 2100 includes a footprint 2140 for an optional fourth inductor. In the example of FIG. 21, this fourth inductor is not present, e.g. the fourth inductor is not “stuffed” on substrate 2108. Accordingly, electrically assembly 2100 may be operated so that coupler 2136 is disabled, because there is no inductor opposite of coupler 2136. On the other hand, if a fourth inductor (not shown) were instead present at inductor footprint 2140, coupler 2136 may be enabled to help minimize magnetic flux from first inductor 1102 from coupling to this fourth inductor.

Discussed below are simulations conducted by Applicant to evaluate various coupler configurations. The simulations show significant benefits of the coupler configurations disclosed herein.

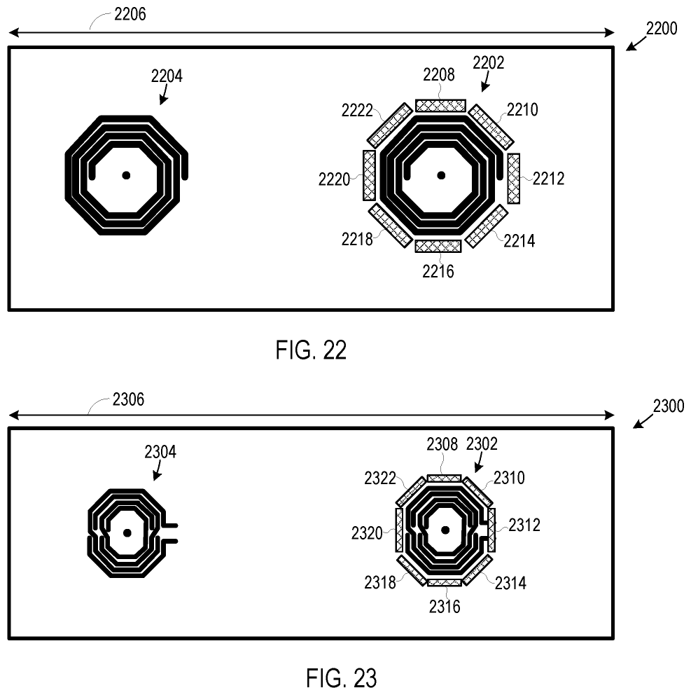

FIG. 22 is a top plan view of an electrically assembly 2200 which includes a first inductor 2202 and second inductor 2204 separated from each other in a direction 2206. First inductor 2202 is similar to first inductor 1102 of FIG. 11, and second inductor 2204 is similar to second inductor 1104 of FIG. 11. Electrically assembly 2200 includes eight couplers 2208-2222 disposed around a perimeter of first inductor 2202. Each coupler 2208-2222 can be selectively enabled and disabled, such as by using a switching device (not shown) in a manner similar to that discussed above with respect to FIG. 21.

Applicant conducted computer simulations of performance of couplers 2208-2222. Table 1 below summarizes the results of the simulations. “L1” is inductance of first inductor 2202; “L1 Q-Factor” is a Q-factor of first inductor 2202; “L1/L10” represents inductance of first inductor 2202 with the specified coupler(s) enabled, over inductance of first inductor 2202 with no couplers enabled; “QL1/QL10” represents Q-factor of first inductor 2202 with the specified coupler(s) enabled, over inductance of first inductor 2202 with no couplers enabled; and dS21 represents change in magnetic coupling of first inductor 2202 to second inductor 2204 with the specified coupler(s) enabled, relative to no couplers being enabled.

TABLE 1

| | | | L1/ | QL1/ | |
|---|---|---|---|---|---|
| | Ll | L1 | L10 | QL10 | dS21 |
| Coupler(s) Enabled | (nH) | Q-factor | (%) | (%) | (dB) |
| No couplers enabled | 2.43 | 12.99 | 100 | 100 | 0.00 |
| All couplers enabled | 2.00 | 8.117 | 82.3 | 62.5 | −5.85 |
| Coupler 2220 enabled | 2.36 | 11.84 | 97.1 | 91.1 | −11.34 |
| Coupler 2212 enabled | 2.36 | 12.01 | 97.3 | 92.5 | 2.81 |
| Coupler 2208 enabled | 2.32 | 11.35 | 95.8 | 87.4 | 1.39 |
| Coupler 2216 enabled | 2.38 | 12.19 | 98.3 | 93.8 | 1.25 |
| Coupler 2222 enabled | 2.32 | 11.44 | 95.6 | 88.1 | −7.61 |
| Coupler 2218 enabled | 2.38 | 12.09 | 98.0 | 93.1 | −2.52 |
| Coupler 2210 enabled | 2.32 | 11.28 | 95.8 | 0 | 3.53 |
| Coupler 2214 enabled | 2.38 | 12.1 | 98.1 | 93.1 | 2.42 |
| Couplers 2218 & 2222 | 2.29 | 11.01 | 94.3 | 84.8 | −16.65 |
| enabled | | | | | |

Table 1 shows that the greatest reduction in magnetic coupling of second inductor 2204 from first inductor 2202 was achieved with couplers to the left of first inductor 2202 enabled. Additionally, Table 1 shows that magnetic coupling was increased when couplers to the right of first inductor 2202 were enabled. Thus, Table 1 teaches that a coupler should be disposed between first inductor 2202 and second inductor 2204 to achieve a greatest reduction in coupling. Additionally, Table 1 shows that greater reduction in coupling can be achieved with only couplers to the left of first inductor 2202 enabled, thereby teaching that a coupler should ideally not surround first inductor 2202, or that portions of a coupler to the right of first inductor 2202 should be significantly displaced from first inductor 2202.

FIG. 23 is a top plan view of an electrically assembly 2300 which includes a first inductor 2302 and second inductor 2304 separated from each other in a direction 2306. First inductor 2302 is similar to first inductor 1302 of FIG. 13, and second inductor 2304 is similar to second inductor 1304 of FIG. 13. Electrically assembly 2300 includes eight couplers 2308-2322 disposed around a perimeter of first inductor 2302. Each coupler 2308-2322 can be selectively enabled and disabled, such as a using a switching device (not shown) in a manner similar to that discussed above with respect to FIG. 21.

Applicant conducted computer simulations of performance of couplers 2308-2324. Table 2 below summarizes the results of the simulations. “L1” is inductance of first inductor 2302; “L1 Q-Factor” is a Q-factor of first inductor 2302; “L1/L10” represents inductance of first inductor 2302 with the specified coupler(s) enabled, over inductance of first inductor 2302 with no couplers enabled; “QL1/QL10” represents Q-factor of first inductor 2302 with the specified coupler(s) enabled, over inductance of first inductor 2302 with no couplers enabled; and dS21 represents change in magnetic coupling of first inductor 2302 to second inductor 2304 with the specified coupler(s) enabled, relative to no couplers being enabled. The data of Table 2 also teaches that best performance is achieved when only couplers to the left of first inductor 2302 are enabled.

TABLE 2

| | | L1 | L1/ | QL1/ | |
|---|---|---|---|---|---|
| | L1 | Q- | L10 | QL10 | dS21 |
| Coupler(s) Enabled | (nH) | factor | (%) | (%) | (dB) |
| No couplers enabled | 2.43 | 12.99 | 100 | 100 | 0.00 |
| All couplers enabled | 2.05 | 8.712 | 84.4 | 67.1 | −4.36 |
| Coupler 2320 enabled | 2.36 | 12.9 | 97.3 | 99.3 | −12.15 |
| Coupler 2312 enabled | 2.38 | 13.19 | 98.0 | 101.5 | 3.33 |
| Coupler 2308 enabled | 2.38 | 13.04 | 98.3 | 100.4 | 1.39 |
| Coupler 2316 enabled | 2.37 | 13.31 | 97.7 | 102.5 | 1.81 |
| Coupler 2324 enabled | 2.38 | 13.05 | 97.9 | 100.5 | −3.8 |
| Coupler 2318 enabled | 2.38 | 13.09 | 98.1 | 100.8 | −2.573 |
| Coupler 2310 enabled | 2.38 | 13.11 | 98.0 | 100.9 | 2.82 |
| Coupler 2314 enabled | 2.38 | 13.01 | 98.1 | 100.2 | 2.76 |
| Couplers 2318 & 2320 | 2.32 | 12.29 | 95.8 | 94.6 | −14.44 |
| enabled | | | | | |

It should be noted that the simulations of Tables 1 and 2 were conducted assuming that the switching devices which selectively enable and disable the couplers have zero resistance, i.e. that the switching devices are ideal. Further simulations showed that switching device resistance may reduce coupler effectiveness, but significant reduction in magnetic coupling of two inductors can still be achieved with switching devices having realistic resistance values.

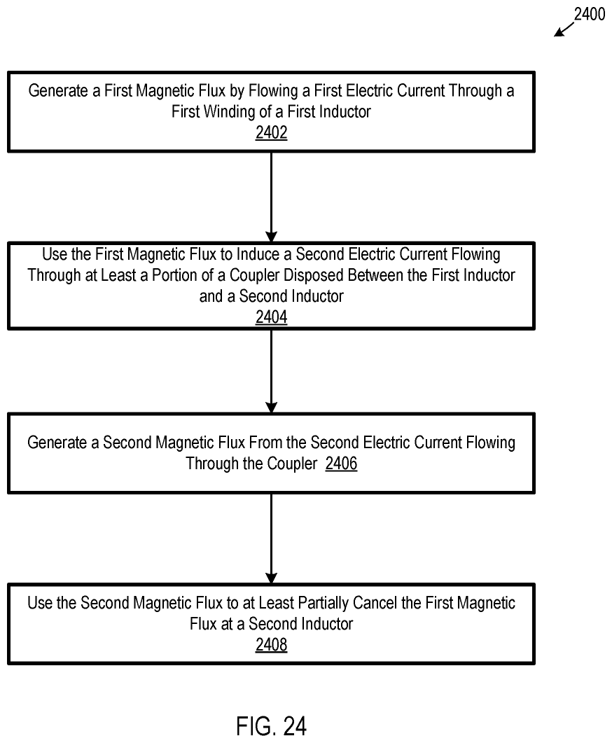

FIG. 24 is a flow chart illustrating a method 2400 for canceling magnetic flux in an electrical assembly. In a block 2402, a first magnetic flux is generated by flowing a first electric current through a first winding of a first inductor. In one example of block 2402, a first magnetic flux is generated by flowing a first electric current through first winding 112 of first inductor 102 (FIG. 1). In a block 2404, the first magnetic flux is used to induce a second electric current flowing through at least a portion of a coupler disposed between the first inductor and a second inductor. In one example of block 2404, the first magnetic flux from first inductor 102 is used to induce a second electric current through coupler 106. In a block 2406, a second magnetic flux is generated from the second electric current flowing through the coupler. In one example of block 2406, a second magnetic flux is generated from the second electric current flowing through coupler 106. In a block 2408, the second magnetic flux is used to at least partially cancel the first magnetic flux at a second inductor. In one example of block 2408, the second magnetic flux from coupler 106 is used to at least partially cancel magnetic flux from first inductor 102 at second inductor 104.

### Combinations of Features

Features described above may be combined in various ways without departing from the scope hereof. The following examples illustrate some possible combinations:

(A1) An electrical assembly may include (1) a first inductor including a first winding wound around a first winding axis, (2) a second inductor separated from the first inductor in a first direction, and (3) a coupler at least partially disposed between the first inductor and the second inductor in the first direction, the coupler forming at least part of an electrical circuit enabling electric current to flow through the coupler.

(A2) In the electrical assembly denoted as (A1), the coupler optionally does not surround the first inductor, as seen when the electrical assembly is viewed cross-sectionally along a direction of the first winding axis.

(A3) In any one of the electrical assemblies noted as (A1) and (A2), the coupler may be asymmetric with respect to a dividing axis of the first inductor extending in a second direction that is at least substantially orthogonal to the first direction.

(A4) In the electrical assembly denoted as (A3), the first winding axis may be orthogonal to each of the first direction and the second direction, and the dividing axis may intersect the first winding axis.

(A5) In any one of the electrical assemblies denoted as (A1) through (A4), the coupler may be configured such that: (1) a first magnetic flux resulting from a first electric current flowing through the first winding induces a second electric current flowing through the coupler, and (2) the second electric current flowing through the coupler induces a second magnetic flux which at least partially cancels the first magnetic flux at the second inductor.

(A6) In any one of the electrical assemblies denoted as (A1) through (A5), (1) the first winding may enclose a first area, as seen when the electrical assembly is viewed cross-sectionally along the direction of the first winding axis, (2) the coupler may include a first portion and a second portion, (3) the first portion may be disposed within the first area, as seen when the electrical assembly is viewed cross-sectionally along the direction of the first winding axis, and (4) the second portion may disposed outside of the first area, as seen when the electrical assembly is viewed cross-sectionally along the direction of the first winding axis.

(A7) Any one of the electrical assemblies denoted as (A1) through (A6) may further include a switching device electrically coupled to the coupler such that flow of electric current through the coupler can be controlled by controlling an operating state of the switching device.

(A8) In any one of the electrical assemblies denoted as (A1) through (A7), the first inductor and the second inductor may be formed on a common printed circuit board.

(A9) In any one of the electrical assemblies denoted as (A1) through (A7), the first inductor and the second inductor may be formed in a common integrated circuit.

(A10) Any one of the electrical assemblies denoted as (A1) through (A9) may further include a third inductor, wherein at least a portion of the coupler is disposed between the first inductor and the third inductor.

(A11) In any one of the electrical assemblies denoted as (A1) through (A10), the first winding may be wound in a spiral shape around the first winding axis.

(A12) In any one of the electrical assemblies denoted as (A1) through (A11), the first inductor may be a differential inductor.

(B1) An electrical assembly may include (1) a first inductor including a first winding wound around a first winding axis extending in a first direction, (2) a second inductor separated from the first inductor, and (3) a coupler disposed between the first inductor and the second inductor and forming at least part of an electrical circuit, the electrical circuit forming at least a partial turn around an additional winding axis extending in a second direction that is different from the first direction.

(B2) In the electrical assembly denoted as (B1), the second direction may be orthogonal to the first direction.

(B3) In any one of the electrical assemblies denoted as (B1) and (B2), the first inductor, the second inductor, and the coupler may each be non-overlapping with each other, as seen when the electrical assembly is viewed cross-sectionally along the first direction.

(B4) Any one of the electrical assemblies denoted as (B1) through (B3) may further include a switching device electrically coupled to the coupler such that flow of electric current through the coupler can be controlled by controlling an operating state of the switching device.

(B5) In any one of the electrical assemblies denoted as (B1) through (B4), the first inductor and the second inductor may be formed on a common printed circuit board.

(B6) In any one of the electrical assemblies denoted as (B1) through (B4), the first inductor and the second inductor may be formed in a common integrated circuit.

(B7) Any one of the electrical assemblies denoted as (B1) through (B6) may further include a third inductor, wherein at least a portion of the coupler is disposed between the first inductor and the third inductor.

(C1) A method for canceling magnetic flux in an electrical assembly may include (1) generating a first magnetic flux by flowing a first electric current through a first winding of a first inductor, (2) using the first magnetic flux to induce a second electric current flowing through at least a portion of a coupler disposed between the first inductor and a second inductor, (3) generating a second magnetic flux from the second electric current flowing through the coupler, and (4) using the second magnetic flux to at least partially cancel the first magnetic flux at the second inductor.

Changes may be made in the above methods, devices, and systems without departing from the scope hereof. It should thus be noted that the matter contained in the above description and shown in the accompanying drawings should be interpreted as illustrative and not in a limiting sense. The following claims are intended to cover generic and specific features described herein, as well as all statements of the scope of the present method and system, which, as a matter of language, might be said to fall therebetween.

What is claimed is:

1. An electrical assembly, comprising:
a first inductor including a first winding wound around a first winding axis;
a second inductor separated from the first inductor in a first direction; and
a coupler at least partially disposed between the first inductor and the second inductor in the first direction, the coupler forming at least part of an electrical circuit enabling electric current to flow through the coupler.

2. The electrical assembly of claim 1, wherein the coupler does not surround the first inductor, as seen when the electrical assembly is viewed cross-sectionally along a direction of the first winding axis.

3. The electrical assembly of claim 1, wherein the coupler is asymmetric with respect to a dividing axis of the first inductor extending in a second direction that is at least substantially orthogonal to the first direction.

4. The electrical assembly of claim 3, wherein:
the first winding axis is orthogonal to each of the first direction and the second direction; and
the dividing axis intersects the first winding axis.

5. The electrical assembly of claim 1, wherein the coupler is configured such that:
a first magnetic flux resulting from a first electric current flowing through the first winding induces a second electric current flowing through the coupler; and
the second electric current flowing through the coupler induces a second magnetic flux which at least partially cancels the first magnetic flux at the second inductor.

6. The electrical assembly of claim 1, wherein:
the first winding encloses a first area, as seen when the electrical assembly is viewed cross-sectionally along the direction of the first winding axis;
the coupler includes a first portion and a second portion;
the first portion is disposed within the first area, as seen when the electrical assembly is viewed cross-sectionally along the direction of the first winding axis; and
the second portion is disposed outside of the first area, as seen when the electrical assembly is viewed cross-sectionally along the direction of the first winding axis.

7. The electrical assembly of claim 1, further comprising a switching device electrically coupled to the coupler such that flow of electric current through the coupler can be controlled by controlling an operating state of the switching device.

8. The electrical assembly of claim 1, wherein the first inductor and the second inductor are formed on a common printed circuit board.

9. The electrical assembly of claim 1, wherein the first inductor and the second inductor are formed in a common integrated circuit.

10. The electrical assembly of claim 1, further comprising a third inductor, wherein at least a portion of the coupler is disposed between the first inductor and the third inductor.

11. The electrical assembly of claim 1, wherein the first winding is wound in a spiral shape around the first winding axis.

12. The electrical assembly of claim 1, wherein the first inductor is a differential inductor.

13. An electrical assembly, comprising:
a first inductor including a first winding wound around a first winding axis extending in a first direction;
a second inductor separated from the first inductor; and
a coupler disposed between the first inductor and the second inductor and forming at least part of an electrical circuit, the electrical circuit forming at least a partial turn around an additional winding axis extending in a second direction that is different from the first direction.

14. The electrical assembly of claim 13, wherein the second direction is orthogonal to the first direction.

15. The electrical assembly of claim 13, wherein the first inductor, the second inductor, and the coupler are each non-overlapping with each other, as seen when the electrical assembly is viewed cross-sectionally along the first direction.

16. The electrical assembly of claim 13, further comprising a switching device electrically coupled to the coupler such that flow of electric current through the coupler can be controlled by controlling an operating state of the switching device.

17. The electrical assembly of claim 13, wherein the first inductor and the second inductor are formed on a common printed circuit board.

18. The electrical assembly of claim 13, wherein the first inductor and the second inductor are formed in a common integrated circuit.

19. The electrical assembly of claim 13, further comprising a third inductor, wherein at least a portion of the coupler is disposed between the first inductor and the third inductor.

20. A method for canceling magnetic flux in an electrical assembly, comprising:
generating a first magnetic flux by flowing a first electric current through a first winding of a first inductor;
using the first magnetic flux to induce a second electric current flowing through at least a portion of a coupler disposed between the first inductor and a second inductor;
generating a second magnetic flux from the second electric current flowing through the coupler; and
using the second magnetic flux to at least partially cancel the first magnetic flux at the second inductor.
